(19) United States
(12) Patent Application Publication
(10) Pub. No.: US 2023/0061147 A1
(43) Pub. Date: Mar. 2, 2023

(54) INTEGRATED METROLOGY SYSTEM

(71) Applicant: NOVA MEASURING INSTRUMENTS LTD., Rehovot (IL)

(72) Inventors: Alex Shichtman, Rehovot (IL); Beni Shulman, Rehovot (IL); Igor Shvartsman, Rehovot (IL)

(73) Assignee: NOVA LTD., Rehovot (IL)

(21) Appl. No.: 17/759,617

(22) PCT Filed: Jan. 27, 2021
(86) PCT No.: PCT/IB2021/050608

§ 371 Date: Jul. 27, 2022

Related U.S. Application Data
(60) Provisional application No. 62/966,152, filed on Jan. 27, 2020.

(51) Int. Cl. H01L 21/67; H01L 21/66

(52) U.S. Cl. CPC H01L 21/67207; H01L 22/12; H01L 21/67242

(57) ABSTRACT

An integrated metrology system for evaluating semiconductor wafers, the metrology system comprises a main body that has a rear side and a front side; the front side defines a front border of the main body; one or more detachable supporting units that are detachably coupled to the main body and support the main body while extending outside the front border; and at least one auxiliary supporting unit that is configured to support the main body at an absence of the one or more detachable supporting units

[symbol]

### CROSS REFERENCE

This application claims priority from U.S. provisional patent 62/966,152 filing date Jan. 27, 2020 which is incorporated herein by reference.

### BACKGROUND

An integrated metrology system should be adapted to integrate with another system—such as a semiconductor manufacturing system, and the like.

The integration usually includes connecting the integrated metrology system to the manufacturing system and allowing an exchange of wafers between the integrated metrology system and the manufacturing system.

The integrated metrology system should fulfill different contradicting needs—it should be compact (for example—exhibit a minimal footprint), be easy to maintain and preform highly accurate metrology processes.

An integrated metrology system may include a powerful light source that dissipates a lot of heat. The dissipated heat may distort the optics of the integrated metrology system.

There is a growing need to provide an efficient integrated metrology system.

### SUMMARY

There may be provided an integrated metrology system.

### BRIEF DESCRIPTION OF THE DRAWINGS

In order to understand the invention and to see how it may be carried out in practice, a preferred embodiment will now be described, by way of non-limiting example only, with reference to the accompanying drawings:

FIG. 1 is a perspective view of an example of an integrated metrology system and another system;

FIG. 2 is a side view of an example of an integrated metrology system and another system;

FIG. 3 is a perspective view of an example of an integrated metrology system and another system;

FIG. 4 is a side view of an example of an integrated metrology system and another system;

FIG. 5 is a top view of an example of an integrated metrology system and another system;

FIG. 6 is a top view of an example of an integrated metrology system and a part of another system;

FIG. 7 is a top view of an example of an integrated metrology system and another system;

FIG. 8 is a top view of an example of an integrated metrology system and a part of another system;

FIG. 9 is a perspective view of an example of an integrated metrology system and another system;

FIG. 10 is a perspective view of an example of an integrated metrology system and another system;

FIG. 11 is a side view of an example of an integrated metrology system and another system;

FIG. 12 is a perspective view of an example of a part of an integrated metrology system and a part of another system;

FIG. 13 is a perspective view of an example of a part of an integrated metrology system;

FIG. 14 is a rear view of an example of an integrated metrology system without some of its exterior panels;

FIG. 15 is a perspective view of an example of an integrated metrology system without some of its exterior panels;

FIG. 16 is a rear view of an example of a part of an integrated metrology system without some of its exterior panels;

FIG. 17 is a perspective view of an example of a mechanical stage and a chuck of an integrated metrology system;

FIG. 18 is a rear view of an example of a mechanical stage and a chuck of an integrated metrology system;

FIG. 19 is a perspective view of an example of a mechanical stage and a chuck of an integrated metrology system;

FIG. 20 is a perspective view of an example of an optical component of an integrated metrology system;

FIG. 21 is a perspective view of an example of a part of an integrated metrology system without some of its exterior panels;

FIG. 22 is a schematic view of a keyboard at different positions;

FIG. 23 is a schematic view of a keyboard at different positions.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated at least one embodiment of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any number, or value illustrated below should be regarded as a non-limiting example.

Any combination of any element and/or units and/or features of any of the systems illustrated in any of the drawings may be provided.

Any combination of any element and/or units and/or features of any of the systems illustrated in the specification may be provided.

Any combination of any subject matter that appears in any of the claims (for example—the originally filed claims) may be provided.

Any one of the drawings may be of scale or may not be of scale.

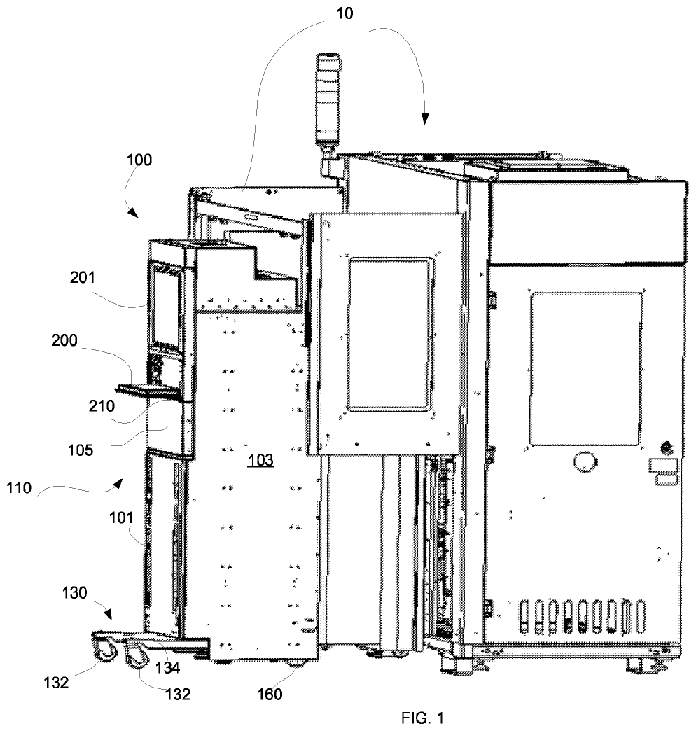

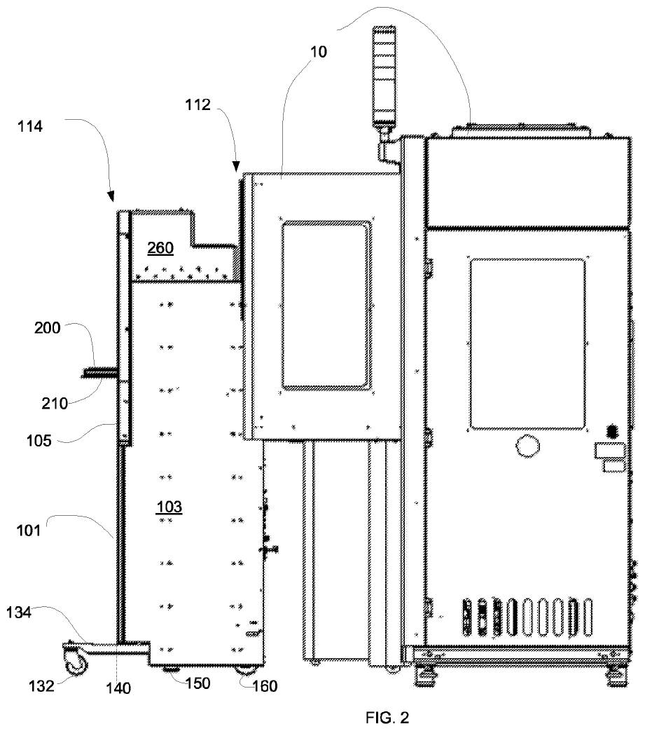

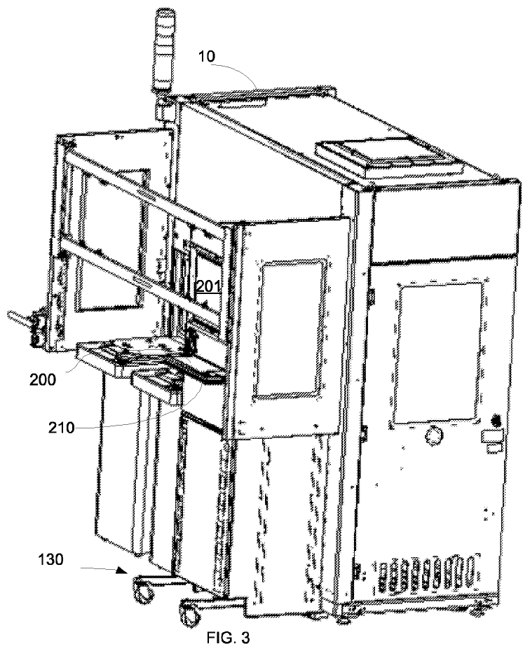

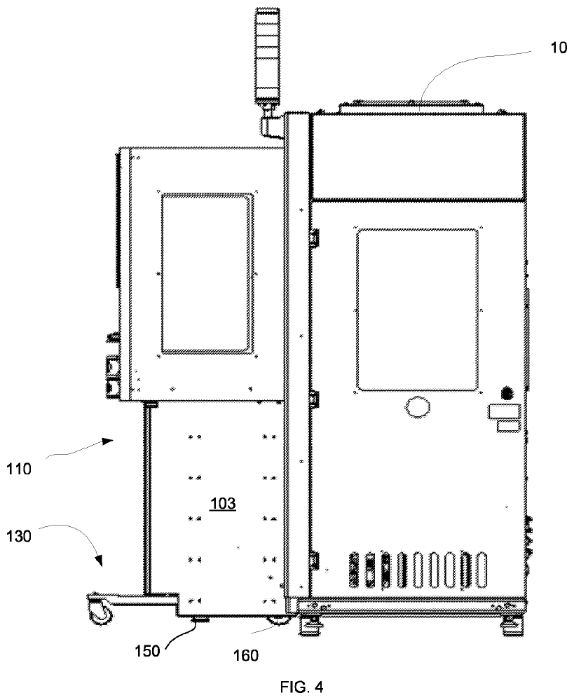

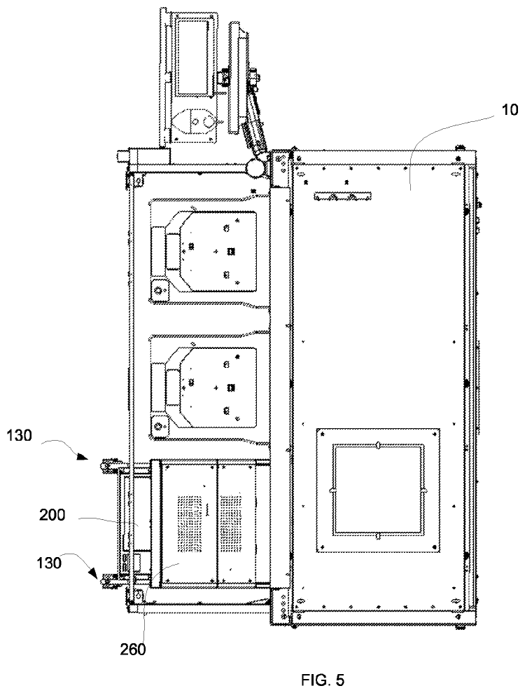

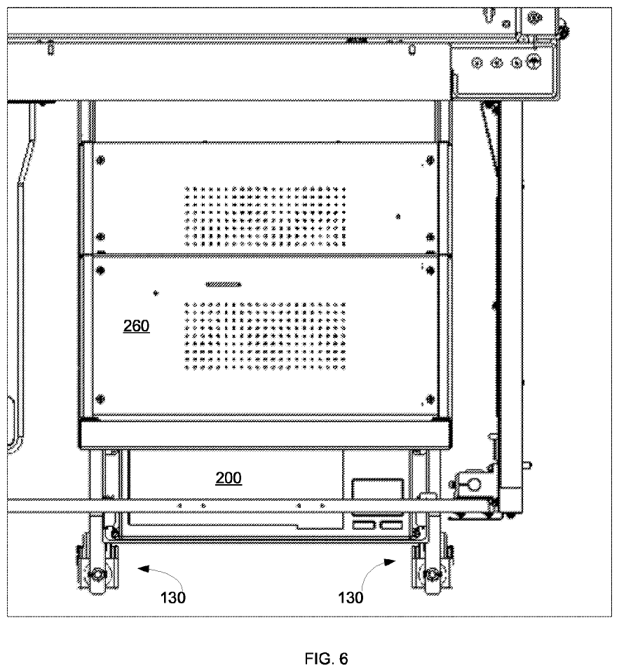

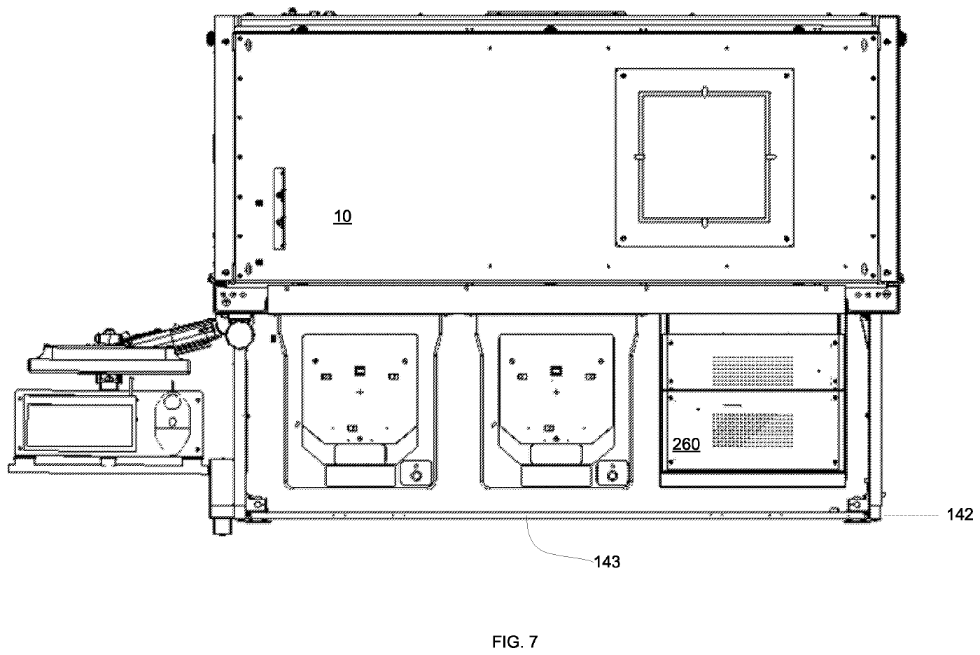

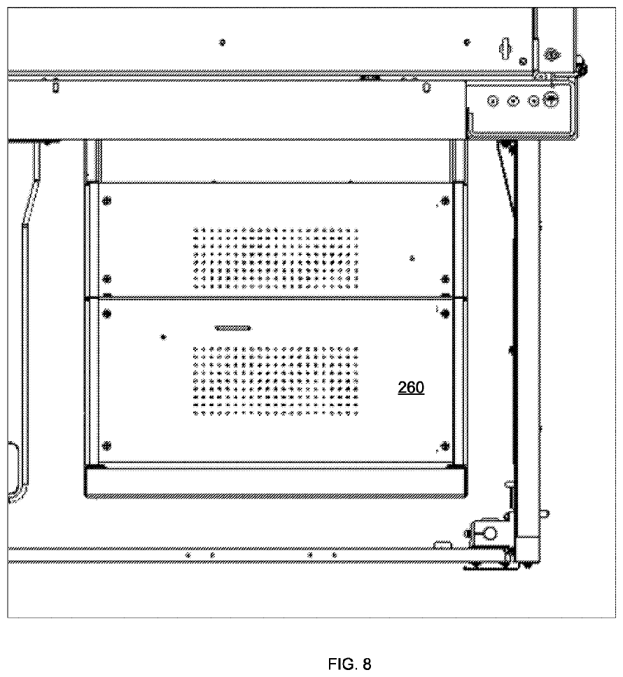

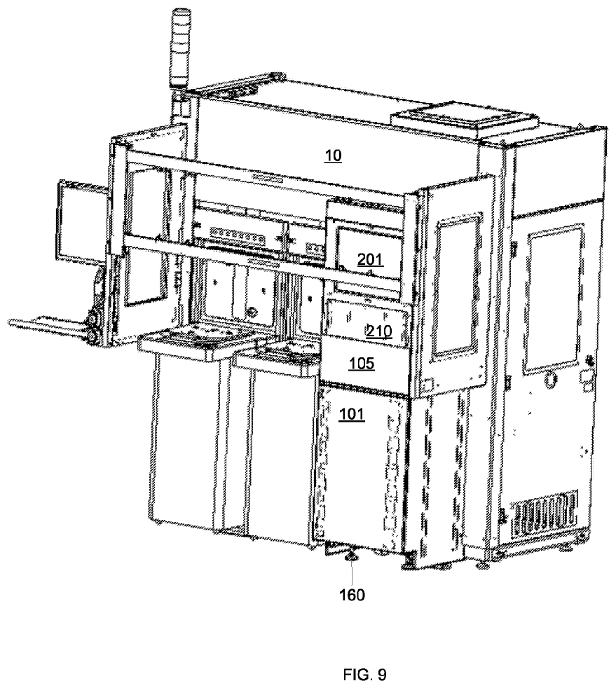

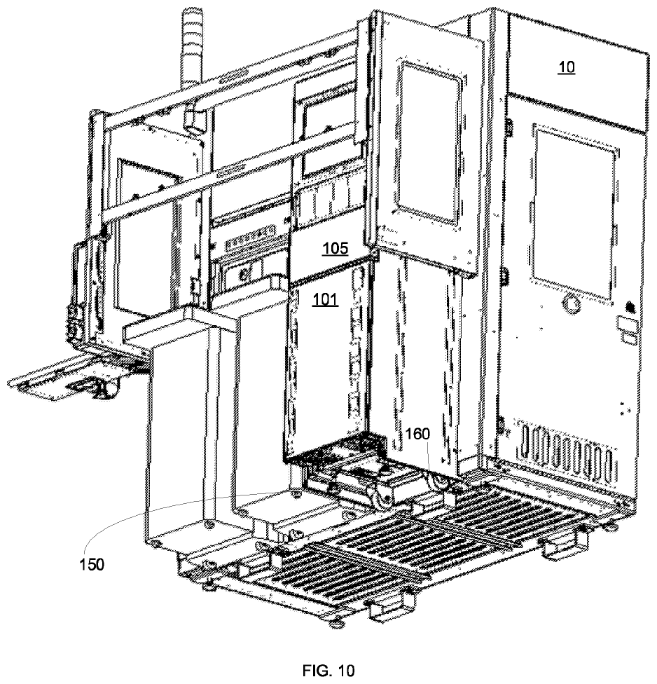

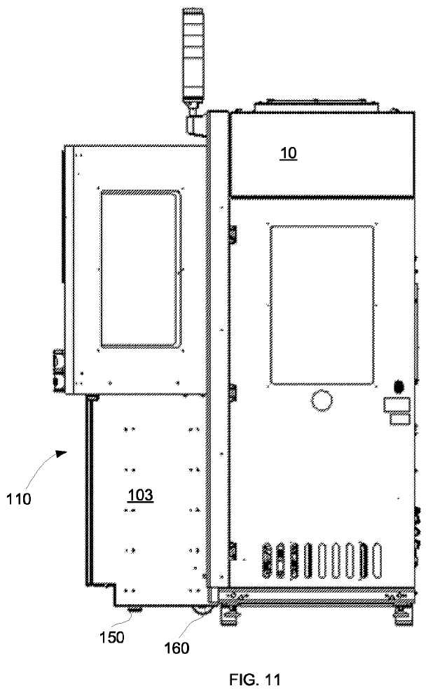

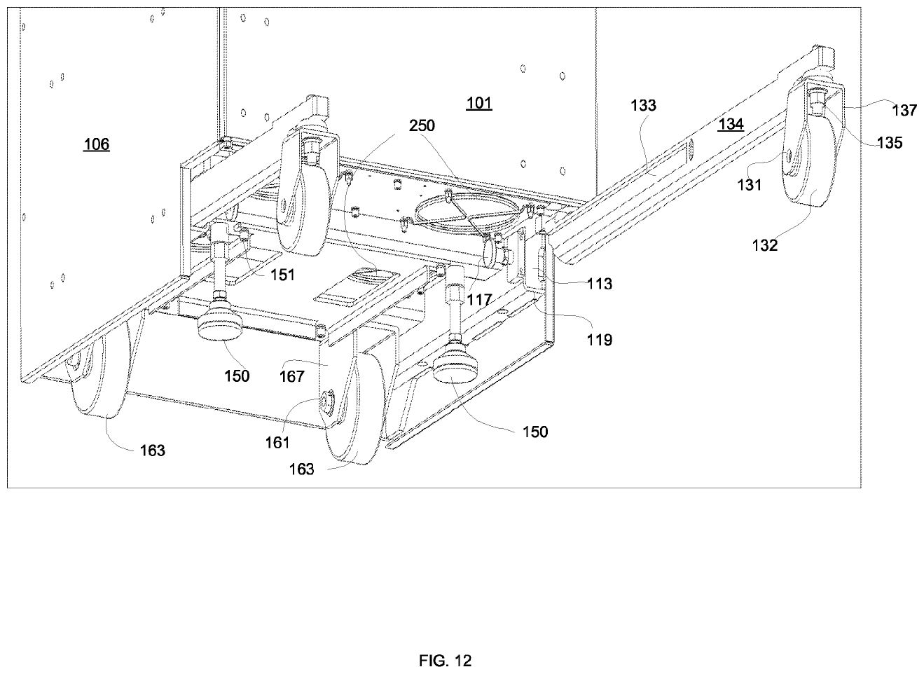

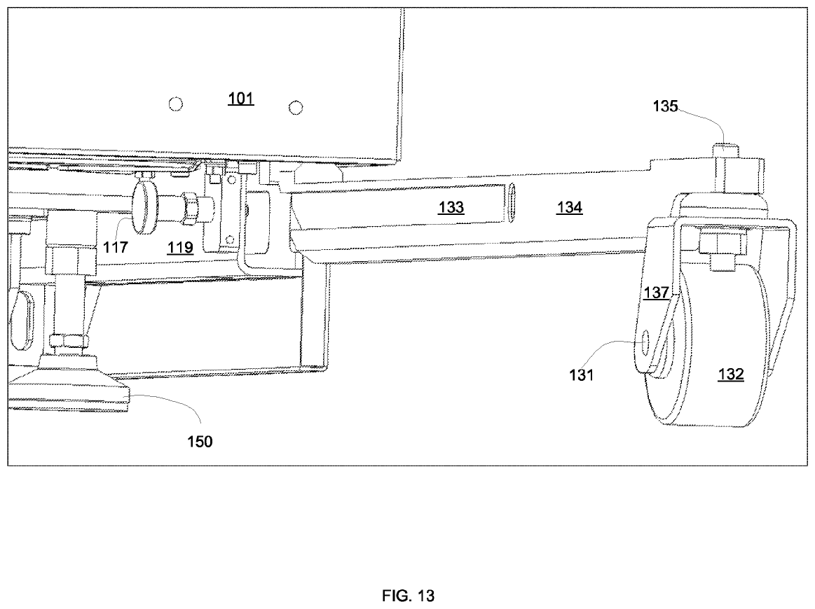

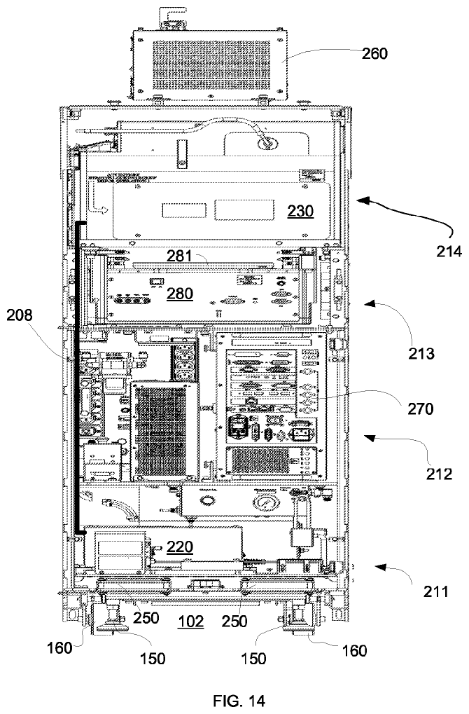

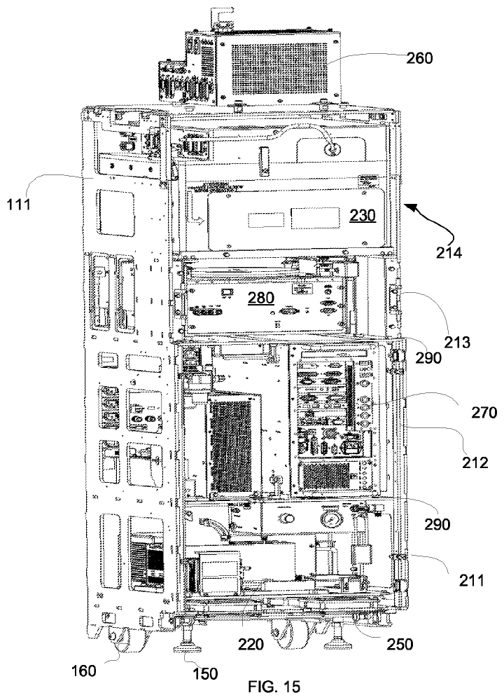

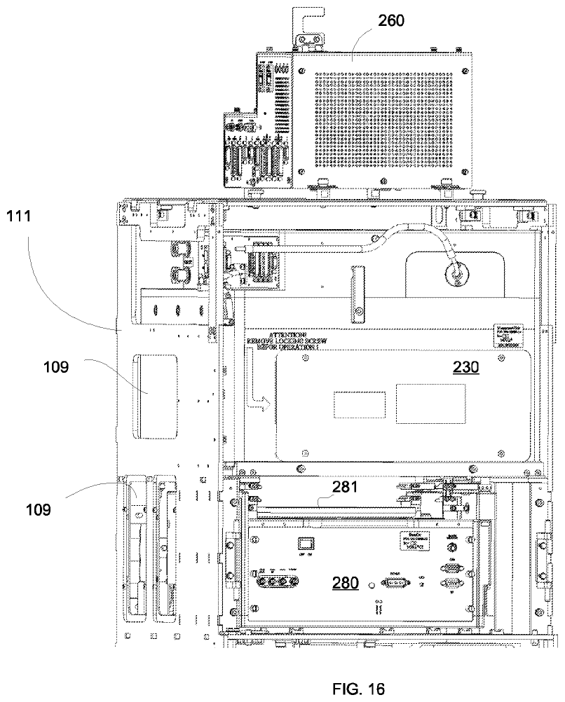

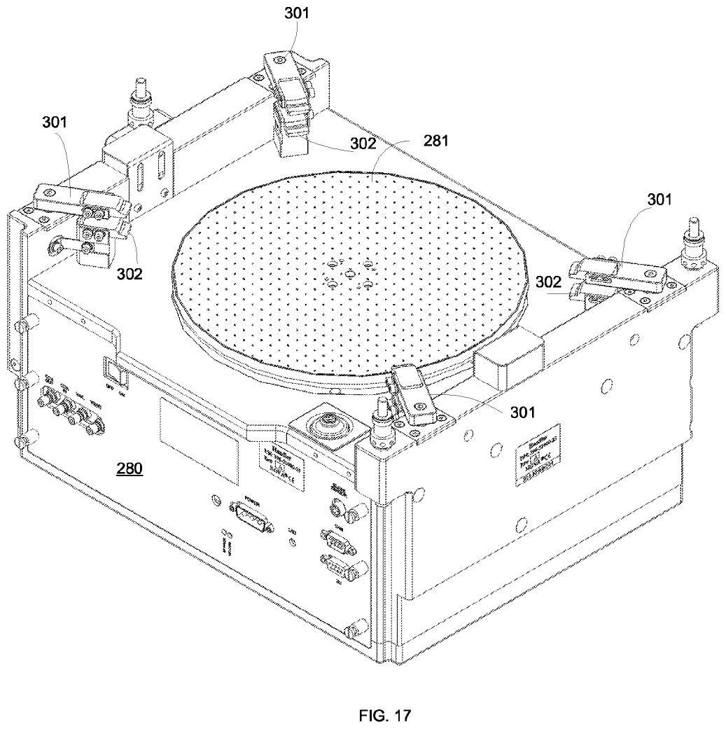

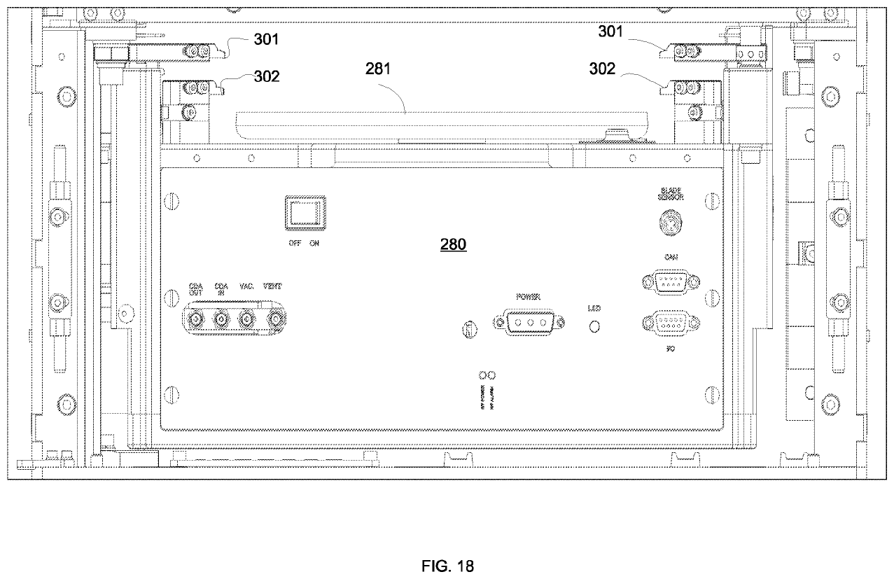

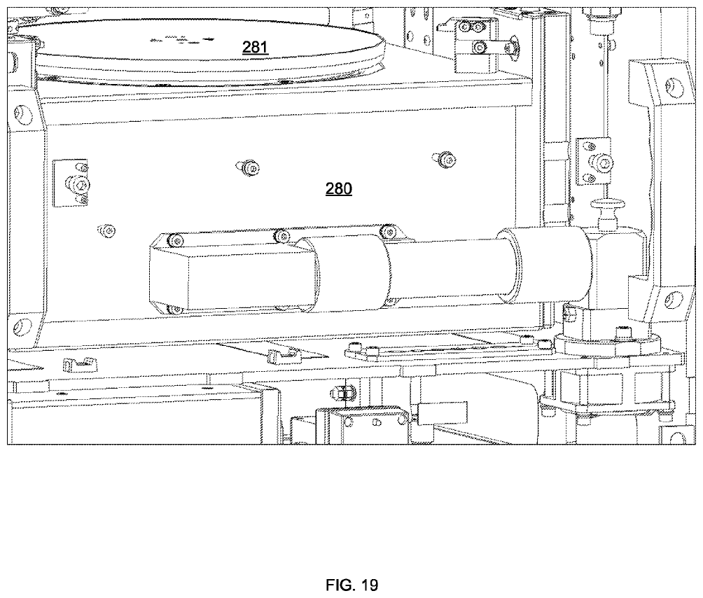

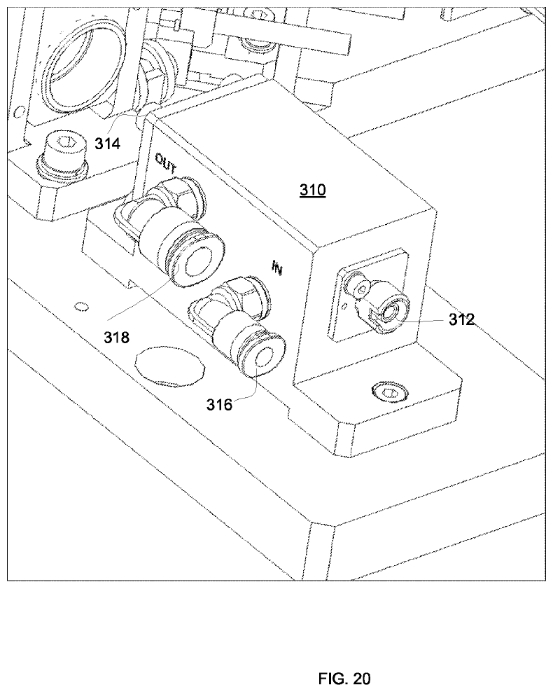

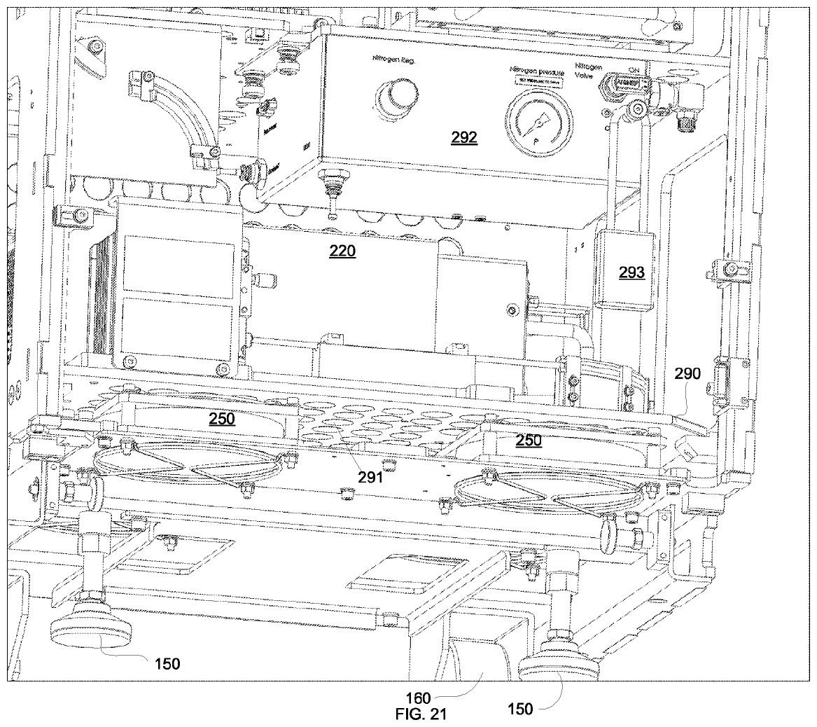

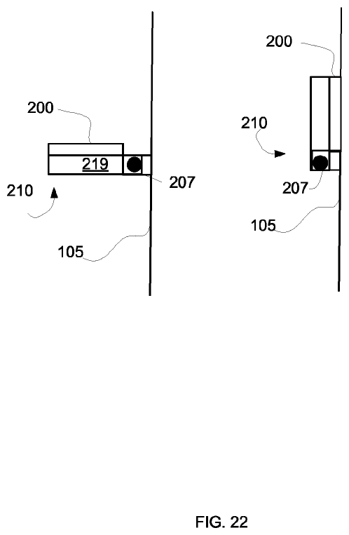

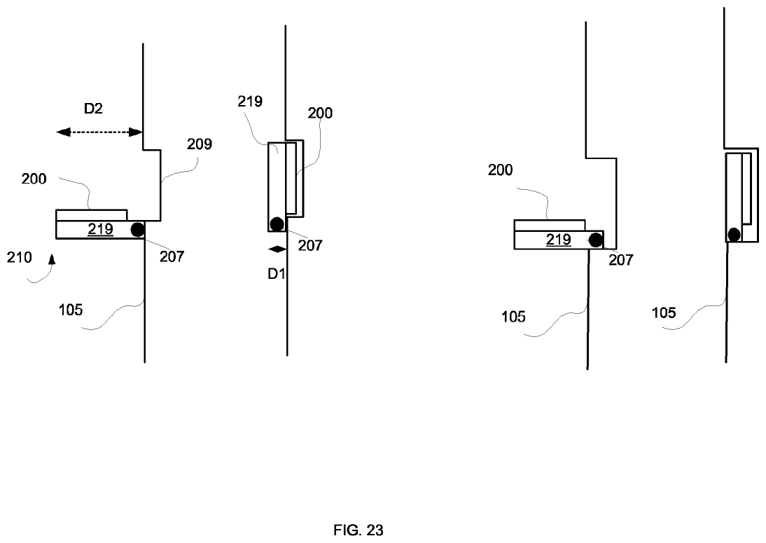

FIG. 1 is a perspective view of an example of an integrated metrology system 100 and another system 10—whereas in FIG. 1 the other system includes an Equipment Front End Module. FIG. 2 is a side view of an example of an integrated metrology system 100 and another system 10. FIG. 3 is a perspective view of an example of an integrated metrology system 100 and another system 10. FIG. 4 is a side view of an example of an integrated metrology system 100 and another system 10. FIG. 5 is a top view of an example of an integrated metrology system 100 and another system 10. FIG. 6 is a top view of an example of an integrated metrology system 100 and a part of another system 10. FIG. 7 is a top view of an example of an integrated metrology system 100 and another system 10 and a so called light curtain 142. FIG. 8 is a top view of an example of an integrated metrology system 100 and a part of another system 10. FIG. 9 is a perspective view of an example of an integrated metrology system 100 and another system 10. FIG. 10 is a perspective view of an example of an integrated metrology system 100 and another system 10. FIG. 11 is a side view of an example of an integrated metrology system 100 and another system 10. FIG. 12 is a perspective view of an example of a part of an integrated metrology system 100 and a part of another system 10. FIG. 13 is a perspective view of an example of a part of an integrated metrology system 100. FIG. 14 is a rear view of an example of an integrated metrology system 100 without some of its exterior panels. FIG. 15 is a perspective view of an example of an integrated metrology system 100 without some of its exterior panels. FIG. 16 is a rear view of an example of a part of an integrated metrology system 100 without some of its exterior panels. FIG. 17 is a perspective view of an example of a mechanical stage and a chuck of an integrated metrology system 100. FIG. 18 is a rear view of an example of a mechanical stage and a chuck of an integrated metrology system 100. FIG. 19 is a perspective view of an example of a mechanical stage and a chuck of an integrated metrology system 100. FIG. 20 is a perspective view of an example of an optical component of an integrated metrology system 100. FIG. 21 is a perspective view of an example of a part of an integrated metrology system 100 without some of its exterior panels. FIGS. 22 and 23 are schematic views of a keyboard at different positions.

Referring to FIGS. 1-5 and 9-11—the integrated metrology system 100 is connected to another system 10 by an interface such as a rear interface. The real interface may mechanically detachable connect the integrated metrology system to the other system.

The integrated metrology system 100 has a front side 114, a rear side 112, and may include:
a. Main body 110. The front of the main body defines a (virtual) front border 140 on the floor beneath the integrated metrology system 100. A safety border 142 may be defined (for example by a user of the integrated metrology system) to be farther away (from the main body) than the front border 140.
b. Display 201.
c. Keyboard 200.
d. Front interface 210 for supporting the keyboard.
e. High power mechanical stage control unit 260 for supplying high voltage control signals to a mechanical stage.
f. Various panels including first front panel 101, second front panel 105, side panel 103, another side panel 106. The panels are detachable and may be detachably coupled to a main body frame 111 of main body 110.
g. One or more detachable supporting units 130—each may include wheel 132 and arm 134.
h. At least one auxiliary supporting unit 150—each may include a leg.
i. At least one additional supporting units 160—each may include an additional wheel 163.

The display 201, keyboard 200, front interface 210, first front panel 101, and second front panel 105 are located at the front side 114 of the integrated metrology system.

Integrated Metrology System with Multiple Support Units

There is provided an integrated metrology system that is both stable and compact.

It has been found that during the transportation of the integrated metrology system, the integrated metrology system should have a large support base which will contribute to the stability of the integrated metrology system during the transportation of the integrated metrology system.

After the integrated metrology system is transported to its desired location—the large support base may not be required—especially as the large support base unnecessarily increases the footprint of the integrated metrology system.

There is provided an integrated metrology system that has (a) a main body 110 that has a rear side and a front side, the rear side faces the other system; the front side defines a front border 140 of the main body; (b) one or more detachable supporting units 130 that are detachably coupled to the main body and support the main body while extending outside the front border; and (c) at least one auxiliary supporting unit 150 that is configured to support the main body at an absence of the one or more detachable supporting units.

After the integrated metrology system 100 is installed (see for example FIG. 9)—the one or more detachable supporting units 130 may be removed and the main body 110 may be supported by the at least one auxiliary supporting unit 150. The at least one auxiliary supporting unit 150 does not extend outside the front border as much as the one or more detachable supporting units do—and may even not extend outside the front border at all.

The support base may be defined by (a) at least one additional supporting unit 160 positioned below the main body and either one of (b) one or more detachable supporting units 130 (when still connected to the main base), and (c) at least one auxiliary supporting unit 150 (when positioned to support the main body.

The distances between the at least one additional supporting unit 160 and the one or more detachable supporting units 130 exceeds the distances between the at least one additional supporting unit 160 and the at least one auxiliary supporting unit 150.

Each supporting unit out of the at least one additional supporting unit, one or more detachable supporting units and the at least one auxiliary supporting unit may be movable in relation to floor on which the integrated metrology system is positioned, or may be fixed.

The at least one auxiliary supporting unit 150 is configured to move in relation to the main body along a first direction (for example upwards and downwards)—between a position (upper position) in which the at least one auxiliary supporting unit contacts the floor and another position (lower position) in which the at least one auxiliary supporting unit does not contact the floor.

The one or more detachable supporting units 130 are configured to move in relation to the main body along a second direction (for example outside the main body—in a horizontal direction).

The first direction may differ from the second direction.

The one or more detachable supporting units 130 may be removed after the at least one auxiliary supporting unit 160 is moved to the lower position—in which they support the main body.

Examples of the various supporting units are shown in FIGS. 12-13. There may be any number of supporting unit of any type (detachable, auxiliary, and additional supporting units).

Each detachable supporting unit 130 includes a wheel 132, and an arm 134. The wheel 132 is illustrated as having two degrees of freedom.

Wheel 132 may rotate about wheel's axis 131. Wheel's axis 131 connected to wheel's housing 137 that in turn is rotatable along further axis 135 (in relation to the main body). In FIGS. 12 and 13 the wheel's axis is horizontal and the further axis is vertical.

The arm 134 may be supported by a support frame 119 that defines a support frame inner space 113 in which the arm 134 may move—for example perform a horizontal movement—towards the main body and outside the main body.

In FIG. 12 the arm 134 is outside the support frame inner space 113 and in FIG. 13 the arm is partially within the support frame inner space 113.

In order to move within the frame inner space, a rear portion of the arm 134 is shaped and sized to move within the support frame inner space 113.

The arm 134 may be fixed to the support frame 119 by a fixation element 117 that is configured to hold the arm at a fixed position while the arm is partially positioned within the frame inner space. The fixation element 117 may be a pin that may be pushed or rotated inside an aperture (maybe a threaded aperture) formed in the support frame—thereby pressing the arm towards another side of the support frame.

The arm 134 may include an arm's cavity 133 in which an edge of the fixation element 117 may be positioned when fixing the position of the arm.

Each additional supporting unit 160 may be positioned below the main body and may include an additional wheel 163 and an additional housing 167. The additional wheel 163 may rotate about an additional axis 161 that is rotatably coupled to the additional housing 167.

The additional housing 167 may be fixed to the main body or may be rotatably coupled to the main body by yet another axis (not shown)—thereby allowing the additional wheel to have two degrees of freedom.

Each additional supporting unit 160 may be closer to the rear side of the main body than the detachable supporting unit 130. Any other position of any of the support units may be provided.

The auxiliary supporting unit 150 may be a leg, may include wheel, may be fixed to the main body or may move in relation to the main body. The movement (between an upper position to a lower position) may be done by rotation, in a linear or non-linear manner.

Movable Keyboard

A safety border (also referred to as “Safety light barrier” and also referred to as “Light Curtain”) (denoted 142 in FIG. 7) may be defined by a user of the integrated metrology system 100. A user may not operate the integrated metrology system 100 (and/or even the other system 10) when any part of the integrated metrology system 100 crosses the safety border 142. There may be provided one or more sensors that monitor the safety border and check whether the keyboard or any other component passed the safety border—and when a crossing occurred—generate an alert, prevent the progress of a manufacturing process, and the like. In FIG. 7 the safety border 142 is defined by a part 143 of a frame of the other device.

The integrated metrology system 100 includes a keyboard that when used extends outside the main body.

Maintaining the keyboard open may either cross the safety border or may force the main body of the integrated metrology system 100 to be small enough to enable the integrated metrology system 100 not to cross the safety border even when the keyboard is open.

There may be provided an integrated metrology system that may include (a) a main body 110 that has a rear side and a front side, the rear side faces another system; the front side defines a front border 140 of the main body, (b) a front interface 210, and (c) a keyboard 200 that is movably coupled, via the front interface 210, to the main body.

The keyboard 200 is configured to be moved between multiple positions, the multiple positions includes a first position and a second position.

When positioned at the first position (Extended position or Open position) the keyboard extends outside the front border 140 by a first distance. The first distance may be about the width of the keyboard.

When positioned at the second position (Folded position or Closed position), the keyboard does not extend outside an imaginary line that is located up to a second distance from the front border, the second distance is smaller than the first distance. The imaginary line may fall on the front border 140—or may be spaced apart from the front border 140.

In FIGS. 1-5 the keyboard is in the first position.

In FIGS. 7-11 the keyboard is at the second position.

FIGS. 22 and 23 illustrate scenarios in which the keyboard is in the first position and additional scenarios in which the keyboard in in the second position.

FIGS. 22 and 23 illustrate a second position in which the keyboard still slightly extends out of the first border and also illustrated a recess 209 formed in the main body in which the keyboard and the front interface may fully or partially enter) when positioned in the second position.

The keyboard (or rather the front interface) may be rotatably coupled to the main body—for example by keyboard axis 207.

The keyboard axis may be located near a top of the keyboard. FIG. 22 illustrates keyboard axis 207 located near a bottom the keyboard.

The second position may be a vertical position or almost vertical position (see FIG. 22) and the first position may be a horizontal position.

The keyboard may be non-rotatably coupled to the main body.

There may be provided a keyboard fixation element for holding (by mechanical means and/or electromagnetic means) the keyboard in the second position.

The keyboard may be replaced by another unit that is movable between different positions—including an open position and closed position.

Heat Evacuation and Maintainable Integrated Metrology System

The integrated metrology system 100 is connected (via a rear interface) to another system. It may be desired to perform maintenance operations without disconnecting the integrated metrology system 100 from the other system.

The integrated metrology system 100 may include a main body frame and multiple panels that protect the main body. The panels are detachably coupled (for example via clips, screws, bolts and nuts) to the main body frame—so that they can be easily removed during maintenance operations. The main body frame may include openings (such as opening 109 of FIG. 16) that ease the access to various parts of the main body.

Furthermore—in order to ease the maintenance and/or to ease upgrades of the integrated metrology system 100—the integrated metrology system 100 may have a modular configuration. Various components of the integrated metrology system 100 may be arranged as detachable modules that are located in multiple compartments of the integrated metrology system 100.

The integrated metrology system 100 may include a very powerful light source that may dissipate a substantial amount of heat.

In order to prevent the heat from distorting optical components of the optical hard and from damaging or distorting other units of the integrated metrology system 100—the light source is spaced away from the optical head. In addition—the heat is conveyed outside the main body of the by one or more air suction element such as air vents.

There may be provided an integrated metrology system 100 for evaluating semiconductor wafers, the metrology system may include a main body 110 that may include optical head 230 and light source 220.

The light source 220 is positioned at a lower portion of the main body. The optical head 230 is positioned an upper portion of the main body.

The optical head 230 is optically coupled to the light source 220 via an optical path that includes an optical cable (denoted 208 in FIG. 14) and may include additional optical components.

FIGS. 14-15 illustrate the main body 110 as including multiple compartments—such as first till fourth compartments 211-214. The first compartment 211 is the lowest compartment and the fourth compartment 214 is the highest compartment.

The optical head 230 is located within fourth compartment 214.

Mechanical stage 280 and chuck 281 are located within third compartment 213.

Computer module 270 is located within second compartment 212.

Light source 220 is located within first compartment 211.

As indicated above—the light source 220 and the optical head 230 are positioned at different compartments of the main body, wherein the optical head 230 is located above the light source 220. In the example set forth in FIGS. 14 and 15—second compartment 212 and third compartment 213 are intermediate compartments that are positioned between the light source 220 and the optical head 230.

As illustrates in FIGS. 14 and 15- and especially in FIG. 21—the air from the vicinity of the light source is evacuated (for example sucked) by one or more air suction elements 250 that are positioned below the light source 220. A perforated plate 290 (including apertures 291) is positioned between the one or more air suction elements 250 and the light source 220 and allow the one or more air suction elements 250 to such air from the space above the one or more air suction elements 250— through the openings formed in the perforated plate 290. Additional perforated plates are shown in FIG. 15. There may be multiple perforated plates at the bottom of one or more compartment.

The air suction elements 250 are positioned at a bottom of the main body and may extend (in part) outside the main body—and in a space 102 located below a lowest compartment of the main body.

The air suction elements may even evacuate air from at least a majority of the main body—for example via apertures formed in the compartments—may such air from second compartment 212 and from any other compartment that is not sealed.

FIG. 14-15 also illustrate that the optical head 230 is positioned below (and even only below) a high power mechanical stage control unit 260 of the integrated metrology system.

The light source 220 may be a laser driven light source.

A power consumption of the light source may exceed 50 watt. For example—it may range between 70 and 140 watts.

FIGS. 17 and 18 illustrates a mechanical stage 280 that support a chuck 281 and move the chuck in various directions (for example—X, Y and Z). There are also provided first end effectors 301 and second end effectors 302. The first end effectors 301 are positioned above the second end effectors 302. The first and second end effectors may be moved in various manners—for example upwards and downwards—in order to allow the first end effectors 301 to receive (from other system 10) a first wafer—while the second end effectors may receive from the chuck support another wafer—that can be taken by the other system.

The following reference numbers were used in the drawings and specification:
10 Another system (other system)
100 Integrated metrology system
101 First front panel
102 Space below the main body
103 Side panel
104 Top Panel
105 Second front panel
106 Another side panel
109 Opening
110 Main body
111 Main body frame
112 Rear side
113 Support frame inner space
114 Front side
116 Rear interface
117 Arm's fixation element
119 Support frame
130 Detachable supporting unit
131 Wheel's axis
132 Wheel
133 Arm's cavity
134 Arm
135 Further axis
137 Wheel's housing
140 Front border
142 Safety border
143 Part of frame of the other system.
150 Auxiliary supporting unit
151 Interface to the auxiliary supporting unit
160 Additional supporting unit
161 Additional axis
163 Additional wheel
167 Additional housing
200 Keyboard
201 Display
207 Keyboard axis
280 Optical cable
209 Recess
210 Front interface
211-215 Compartments
219 Plate
220 Light source
230 Optical head
240 Optical cable
250 Air suction element
270 Computer module
280 Mechanical stage
281 Chuck
290 Perforated plate
291 Apertures
292 Nitrogen source
293 Lock
301 First end effectors
302 Second end effectors
310 Optical coupler
312 Optical input
314 Optical output
316 Gas input
318 Gas output

There may be provided an integrated metrology system for evaluating semiconductor wafers, the metrology system may include: a main body that may have a rear side and a front side; the front side defines a front border of the main body; one or more detachable supporting units that may be detachably coupled to the main body and support the main body while extending outside the front border; and at least one auxiliary supporting unit that may be configured to support the main body at an absence of the one or more detachable supporting units.

The integrated metrology system may include at least one auxiliary supporting unit that may be configured to support the main body without extending outside the front border.

The at least one auxiliary supporting unit may be movable in relation to the main body.

The at least one auxiliary supporting unit may be configured to move in relation to the main body along a first direction; wherein the one or more detachable supporting units may be configured to move in relation to the main body along a second direction; wherein the first direction differs from the second direction.

The second direction may be a vertical direction and the first direction may be a horizontal direction.

The one or more detachable supporting units may include a wheel and an arm.

The main body may include a support frame that defines a support frame inner space; wherein a rear portion of the arm may be shaped and sized to move within the frame inner space.

The integrated metrology system may include a fixation element that may be configured to hold the arm at a fixed position while the arm may be partially positioned within the support frame inner space.

The arm may include a cavity and wherein the fixation element may have an edge that may be shaped and size to enter the cavity.

The integrated metrology system may include at least one additional supporting unit positioned below the main body.

The at least one additional supporting unit may be closer to the rear side of the main body than the detachable supporting unit.

The at least one additional supporting unit may have a single degree of freedom.

The one or more detachable supporting units may include a wheel and an arm, wherein the wheel may be rotatable about a wheels axis, and wherein the wheel's axis may be rotatable in relation to the arm.

The one or more detachable supporting units may include a wheel and an arm, wherein the wheel may be rotatable about a wheel's axis, wherein the wheel's axis may be coupled to a wheel's housing, wherein the wheel's housing may be rotatable in relation to the arm.

There may be provided an integrated metrology system for evaluating semiconductor wafers, the metrology system may include: a main body that may have a rear side and a front side; the front side defines a front border of the main body; a front interface; a keyboard that may be movably coupled to the main body; wherein the keyboard may be configured to be moved between multiple positions, the multiple positions may include a first position and a second position; wherein when positioned at the first position the keyboard extends outside the front border by a first distance; and wherein when positioned at the second position, the keyboard does not extend outside an imaginary line that may be located up to a second distance from the front border, wherein the second distance may be smaller than the first distance.

The integrated metrology system wherein the second position may be a folded position and the first position may be an extended position.

The keyboard may be rotatably coupled to the main body.

The keyboard may be rotatably coupled to the main body via an axis located near a bottom the keyboard when positioned in the second position.

The second position may be a vertical position and the first position may be a horizontal position.

The keyboard may be non-rotatably coupled to the main body.

The when positioned at the second position, the keyboard does not extend outside the front border.

The when positioned at the second position, the keyboard extends outside the front border by the second distance.

The integrated metrology system may include a rear interface that mechanically interfaces the integrated metrology system with an other system.

The integrated metrology system may include a rear interface that mechanically interfaces the integrated metrology system with an equipment front end module of a semiconductor manufacturing system.

The front interface may include an axis and wherein the keyboard may be configured to rotate about the axis while moving between the multiple positions.

The integrated metrology system may include a fixation element for holding the unit in the second position.

The integrated metrology system may include a recess, wherein when in the second position, at least a part of the keyboard may be located within the recess.

There may be provided an integrated metrology system for evaluating semiconductor wafers, the metrology system may include a main body that may include an optical head and a light source; wherein the light source may be positioned at a lower portion of the main body; and wherein the optical head may be positioned at an upper portion of the main body; and wherein the optical head may be optically coupled to the light source via an optical path that may include an optical cable and optical coupler.

The light source and the optical head may be positioned at different compartments of the main body, wherein the optical head may be located above the light source.

The main body may include multiple intermediate compartments that may be positioned between the light source and the optical head.

The integrated metrology system may include detachable modules that may be detachably coupled to the intermediate compartments.

The light source may be positioned within a perforated compartment

The main body may include a main body frame and multiple panels that may be detachably coupled to the main body frame.

The integrated metrology system may include air suction elements positioned at a bottom of the main body.

The integrated metrology system may include air suction elements configured to evacuate air from at least a vicinity of the light source towards a space located below a lowest compartment of the main body.

The air suction elements may be fans.

The integrated metrology system may include air suction elements configured to evacuate air from at least a majority of the main body.

The integrated metrology system may include air suction elements configured to evacuate air from the light source but not from the optical head.

The light source may be positioned within a lowest compartment of the main body.

The optical head may be positioned below a high power mechanical stage control unit of the integrated metrology system.

The integrated metrology system may include multiple compartments and multiple detachable modules that may be detachably coupled to the multiple compartments.

The multiple detachable modules may include a computer module.

The light source may be a laser driven light source.

A power consumption of the light source may exceed 50 watt. For example—it may range between 70 and 140 watts.

The integrated metrology system may include multiple compartments, wherein at least some compartments may be sealed and at least some other compartments may be not sealed.

The integrated metrology system may include multiple compartments, wherein at least one compartment may have a perforated bottom and at least one other compartments may have a non-perforated bottom.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation; a single operation may be distributed in additional operations and operations may be executed at least partially overlapping in time. Moreover, alternative embodiments may include multiple instances of an operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also for example, the examples, or portions thereof, may implemented as soft or code representations of physical circuitry or of logical representations convertible into physical circuitry, such as in a hardware description language of any appropriate type.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

The terms “including”, “comprising”, “having”, “consisting” and “consisting essentially of” are used in an interchangeable manner. For example—any method may include at least the steps included in the figures and/or in the specification, only the steps included in the figures and/or the specification.

We claim:

1. An integrated metrology system for evaluating semiconductor wafers, the metrology system comprises:
a main body that has a rear side and a front side; the front side defines a front border of the main body;
one or more detachable supporting units that are detachably coupled to the main body and support the main body while extending outside the front border; and
at least one auxiliary supporting unit that is configured to support the main body at an absence of the one or more detachable supporting units.

2. The integrated metrology system according to claim 1 comprising at least one auxiliary supporting unit that is configured to support the main body without extending outside the front border.

3. The integrated metrology system according to claim 1 wherein the at least one auxiliary supporting unit is movable in relation to the main body.

4. The integrated metrology system according to claim 1 wherein the at least one auxiliary supporting unit is configured to move in relation to the main body along a first direction; wherein the one or more detachable supporting units are configured to move in relation to the main body along a second direction; wherein the first direction differs from the second direction.

5. The integrated metrology system according to claim 4 wherein the second direction is a vertical direction and the first direction is a horizontal direction.

6. The integrated metrology system according to claim 1 wherein the one or more detachable supporting units comprises a wheel and an arm.

7. The integrated metrology system according to claim 6 wherein main body comprises a support frame that defines a support frame inner space; wherein a rear portion of the arm is shaped and sized to move within the frame inner space.

8. The integrated metrology system according to claim 7 comprising a fixation element that is configured to hold the arm at a fixed position while the arm is partially positioned within the support frame inner space.

9. The integrated metrology system according to claim 8 wherein the arm comprises a cavity and wherein the fixation element has an edge that is shaped and size to enter the cavity.

10. The integrated metrology system according to claim 1 comprising at least one additional supporting unit positioned below the main body.

11. The integrated metrology system according to claim 10 wherein the at least one additional supporting unit is closer to the rear side of the main body than the detachable supporting unit.

12. The integrated metrology system according to claim 10 wherein the at least one additional supporting unit has a single degree of freedom.

13. The integrated metrology system according to claim 1 wherein the one or more detachable supporting units comprises a wheel and an arm, wherein the wheel is rotatable about a wheels axis, and wherein the wheel's axis is rotatable in relation to the arm.

14. The integrated metrology system according to claim 1 wherein the one or more detachable supporting units comprises a wheel and an arm, wherein the wheel is rotatable about a wheel's axis, wherein the wheel's axis is coupled to a wheel's housing, wherein the wheel's housing is rotatable in relation to the arm.

15. The integrated metrology system according to claim 1 comprising a keyboard that is movably coupled to the main body; wherein the keyboard is configured to be moved between multiple positions, the multiple positions comprise a first position and a second position; wherein when positioned at the first position the keyboard extends outside the front border by a first distance; and wherein when positioned at the second position, the keyboard does not extend outside an imaginary line that is located up to a second distance from the front border, wherein the second distance is smaller than the first distance.

16. The integrated metrology system according to claim 15 wherein the second position is a folded position and the first position is an extended position.

17. The integrated metrology system according to claim 1 wherein the main body comprises an optical head and a light source; wherein the light source is positioned at a lower portion of the main body; and wherein the optical head is positioned at an upper portion of the main body; and wherein the optical head is optically coupled to the light source via an optical path that comprises an optical cable.

18. An integrated metrology system for evaluating semiconductor wafers, the metrology system comprises: a main body that has a rear side and a front side; the front side defines a front border of the main body; a front interface; a keyboard that is movably coupled to the main body; wherein the keyboard is configured to be moved between multiple positions, the multiple positions comprise a first position and a second position; wherein when positioned at the first position the keyboard extends outside the front border by a first distance; and wherein when positioned at the second position, the keyboard does not extend outside an imaginary line that is located up to a second distance from the front border, wherein the second distance is smaller than the first distance.

19. The integrated metrology system according to claim 18 wherein the second position is a folded position and the first position is an extended position.

20. The integrated metrology system according to claim 18 wherein the keyboard is rotatably coupled to the main body.

21. The integrated metrology system according to claim 20 wherein the keyboard is rotatably coupled to the main body via an axis located near a bottom the keyboard when positioned in the second position.

22. The integrated metrology system according to claim 18 wherein the second position is a vertical position and the first position is a horizontal position.

23. The integrated metrology system according to claim 18 wherein the keyboard is non-rotatably coupled to the main body.

24. The integrated metrology system according to claim 18 wherein when positioned at the second position, the keyboard does not extend outside the front border.

25. The integrated metrology system according to claim 18 wherein when positioned at the second position, the keyboard extends outside the front border by the second distance.

26. The integrated metrology system according to claim 18 comprising a rear interface that mechanically interfaces the integrated metrology system with an other system.

27. The integrated metrology system according to claim 18 comprising a rear interface that mechanically interfaces the integrated metrology system with an equipment front end module of a semiconductor manufacturing system.

28. The integrated metrology system according to claim 18 wherein the front interface comprises an axis and wherein the keyboard is configured to rotate about the axis while moving between the multiple positions.

29. The integrated metrology system according to claim 18 comprising a fixation element for holding the unit in the second position.

30. The integrated metrology system according to claim 18 comprising a recess, wherein when in the second position, at least a part of the keyboard is located within the recess.

31. The integrated metrology system according to claim 18 wherein the main body comprises an optical head and a light source; wherein the light source is positioned at a lower portion of the main body; and wherein the optical head is positioned at an upper portion of the main body; and wherein the optical head is optically coupled to the light source via an optical path that comprises an optical cable.

32. The integrated metrology system according to claim 18 wherein the main body has a rear side and a front side; the front side defines a front border of the main body;
wherein the integrated metrology system comprises one or more detachable supporting units that are detachably coupled to the main body and support the main body while extending outside the front border; and at least one auxiliary supporting unit that is configured to support the main body at an absence of the one or more detachable supporting units.

33. An integrated metrology system for evaluating semiconductor wafers, the metrology system comprises:
a main body that comprises an optical head and a light source;
wherein the light source is positioned at a lower portion of the main body; and
wherein the optical head is positioned at an upper portion of the main body; and
wherein the optical head is optically coupled to the light source via an optical path that comprises an optical cable.

34. The integrated metrology system according to claim 33 wherein the light source and the optical head are positioned at different compartments of the main body, wherein the optical head is located above the light source.

35. The integrated metrology system according to claim 34 wherein the main body comprises multiple intermediate compartments that are positioned between the light source and the optical head.

36. The integrated metrology system according to claim 35 comprising detachable modules that are detachably coupled to the intermediate compartments.

37. The integrated metrology system according to claim 33 wherein the light source is positioned within a perforated compartment.

38. The integrated metrology system according to claim 33 wherein the main body comprises a main body frame and multiple panels that are detachably coupled to the main body frame.

39. The integrated metrology system according to claim 33 comprising air suction elements positioned at a bottom of the main body.

40. The integrated metrology system according to claim 33 comprising air suction elements configured to evacuate air from at least a vicinity of the light source towards a space located below a lowest compartment of the main body.

41. The integrated metrology system according to claim 40 wherein the air suction elements are fans.

42. The integrated metrology system according to claim 33 comprising air suction elements configured to evacuate air from at least a majority of the main body.

43. The integrated metrology system according to claim 33 comprising air suction elements configured to evacuate air from the light source but not from the optical head.

44. The integrated metrology system according to claim 33 wherein the light source is positioned within a lowest compartment of the main body.

45. The integrated metrology system according to claim 33 wherein the optical head is positioned below a high power mechanical stage control unit of the integrated metrology system.

46. The integrated metrology system according to claim 33 comprising multiple compartments and multiple detachable modules that are detachably coupled to the multiple compartments.

47. The integrated metrology system according to claim 46 wherein the multiple detachable modules comprises a computer module.

48. The integrated metrology system according to claim 33 wherein the light source is a laser driven light source.

49. The integrated metrology system according to claim 33 wherein a power consumption of the light source exceeds 50 watt.

50. The integrated metrology system according to claim 33 comprising multiple compartments, wherein at least some compartments are sealed and at least some other compartments are not sealed.

51. The integrated metrology system according to claim 33 comprising multiple compartments, wherein at least one compartment has a perforated bottom and at least one other compartments has a non-perforated bottom.

52. The integrated metrology system according to claim 33 comprising a keyboard that is movably coupled to the main body; wherein the keyboard is configured to be moved between multiple positions, the multiple positions comprise a first position and a second position; wherein when positioned at the first position the keyboard extends outside the front border by a first distance; and wherein when positioned at the second position, the keyboard does not extend outside an imaginary line that is located up to a second distance from the front border, wherein the second distance is smaller than the first distance.

53. The integrated metrology system according to claim 33 wherein the second position is a folded position and the first position is an extended position.

54. The integrated metrology system according to claim 33 wherein the main body has a rear side and a front side; the front side defines a front border of the main body; and
wherein the integrated metrology system comprises one or more detachable supporting units that are detachably coupled to the main body and support the main body while extending outside the front border; and at least one auxiliary supporting unit that is configured to support the main body at an absence of the one or more detachable supporting units.
